(19) United States
(12) Patent Application Publication
(10) Pub. No.: US 2003/0192002 A1
(43) Pub. Date: Oct. 9, 2003

(54) Error correcting decoder

(75) Inventors: Peter Sweeney, Surrey (GB); Nicholas Weiner, Bristol (GB)

Correspondence Address: LAHIVE & COCKFIELD, 28 STATE STREET, BOSTON, MA, 02109, US

(73) Assignee: Phyworks Limited, Bristol (GB)

(21) Appl. No.: 10/132,953

(22) Filed: Apr. 26, 2002

(30) Foreign Application Priority Data
Apr. 5, 2002 (GB) 0208011.7

(51) Int. Cl. H04L 1/00; G06F 11/00; G06F 11/30; H03M 13/00; G08C 25/00

(52) U.S. Cl. 714/755

(57) ABSTRACT

A soft-input/soft-output decoder for product codes attempts to define a candidate codeword for each component code in the received data. Depending on the degree of similarity between the candidate codeword and the received component code, an assumption is made about the reliability of the selected candidate code. The received soft-input data is modified, based on the assumed reliability of the selected candidate code.

The resulting decoder is computationally efficient, and suitable for decoding received data signals at optical data rates.

This invention relates to an error correcting decoder, and in particular to a decoding method which can be used for retrieving source data from a received signal.

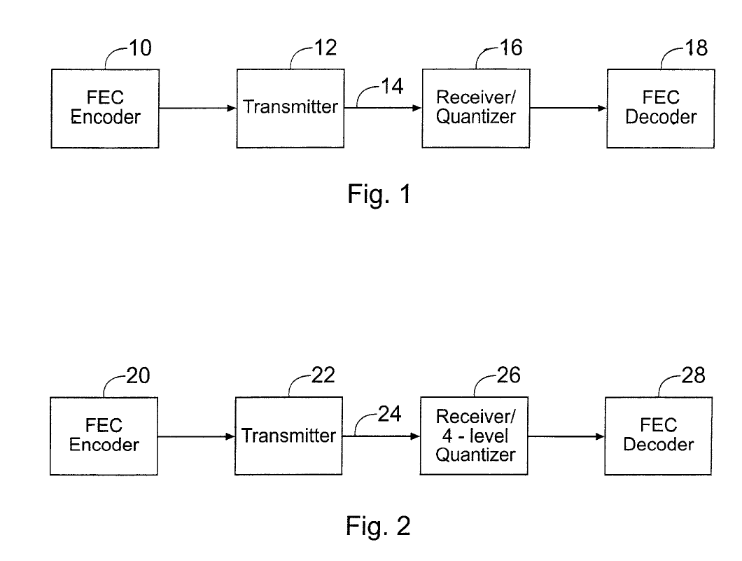

FIG. 1 is a block schematic diagram of a conventional data transmission system, using forward error correction (FEC).

In a communications channel using a systematic forward error correction coding scheme, the data to be communicated, the source data, is encoded using a forward error correction encoder. The encoder 10 computes parity bits, which are transmitted together with the source data. The consequence of combining the parity bits with the source data bits is that only a small fraction of all possible binary sequences (of the combined length) are used for transmission. The binary sequences that are used are referred to as the “codewords”.

The source data and parity bits are transmitted by the transmitter 12 over the communications medium 14. The waveform which subsequently arrives at the receiver 16 is the transmitted waveform, but with distortions and attenuation caused by the medium, and with the addition of noise.

For each received bit, the quantizer 16 determines whether the transmitted binary value is more likely to have been a “1” or a “0”.

The FEC decoder 18 performs Forward Error Correction decoding. This process may be summarised as i) identifying whether a received binary sequence is a codeword; and ii) for cases where the received binary sequence is not a codeword, because the distortions and noise introduced by the communications medium have caused one or more errors in the received binary sequence as compared with the transmitted codeword, finding the codeword which is most likely to have been transmitted.

For any two binary sequences of the same length, the number of bits which are different is referred to as the Hamming distance between the two sequences. In the case of a set of available codewords, it is useful to consider the minimum Hamming distance which exists between any two of the codewords in the set. This is referred to as the minimum distance dₘᵢₙ of the coding scheme (or the dₘᵢₙ of the “code”). This is relevant because it determines the number of bit errors which can be corrected in a received binary sequence.

More specifically, the error correcting capability of a code is given by (dₘᵢₙ−1)/2. For example, the family of coding schemes known as Hamming Codes have dₘᵢₙ=3, and allow correction of a single bit error. The family of Extended Hamming Codes have dₘᵢₙ=4.

In general terms, an Extended Hamming code can be summarised as a set of 2ⁿ−n−1 data bits (for some integer n) together with an n-bit parity code and a parity check bit. In fact, fewer than the 2ⁿ−n−1 data bits may be transmitted, if the code is “shortened”.

As mentioned above, the minimum Hamming distance dₘᵢₙ for an extended Hamming code is 4.

A two-dimensional product of such extended Hamming codes comprises the source data bits, arranged as a rectangular array, together with the parity code and a check bit for each row and each column.

The receiver 16 may use only hard decision (binary) quantization. That is, for each bit in the received waveform, the quantizer outputs one bit. Specifically, for each received bit, the quantizer determines whether the transmitted binary value is more likely to have been a “1” or a “0”, and outputs a bit having the corresponding value.

Alternatively, the receiver may use soft decision quantization, namely quantization into more than two levels.

The document “Near-Optimum Decoding of Product Codes: Block Turbo Codes” IEEE Transactions on Communications, vol. 46, no. 8, August 1998, pp 1003-1010, R. M. Pyndiah, describes an iterative decoding scheme for product codes. The method uses a soft-input/soft-output decoder, and attempts to find an optimum output codeword for each received component code by reviewing multiple candidate codewords. The method chooses between the reviewed codewords by ranking the reliability of the received data bits. This requires a high degree of quantization in the decoder, that is, it requires multiple confidence bits to be assigned to each received bit.

According to the present invention, there is provided a decoder which uses soft input values for each received bit. That is, for each received bit, the quantizer determines whether the transmitted binary value, or “polarity”, is more likely to have been a “1” or a “0”, and further assigns a confidence level to that determination.

Based on these values, the decoder defines a candidate code word for each component code in the received data. Depending on the results of the search for a candidate code word, the received data can be modified. This process can be repeated a number of times for each component code in the data set.

The output corrected data are then generated from the modified received data.

The method is disclosed with reference to a four level quantizer, that is, the quantizer determines whether the transmitted polarity is more likely to have been a 1 or a 0 and further outputs one confidence bit, indicating a higher or lower level of confidence associated with the polarity.

The algorithm described is of relatively low computational complexity, and thus is particularly suitable for use in a fibre optic receiver, with high received bit rates.

For a better understanding of the present invention, reference will now be made, by way of example, to the accompanying drawings.

FIG. 1 is a block schematic diagram of a conventional Forward Error Correction coding system.

FIG. 2 is a block schematic diagram of a system in accordance with the invention.

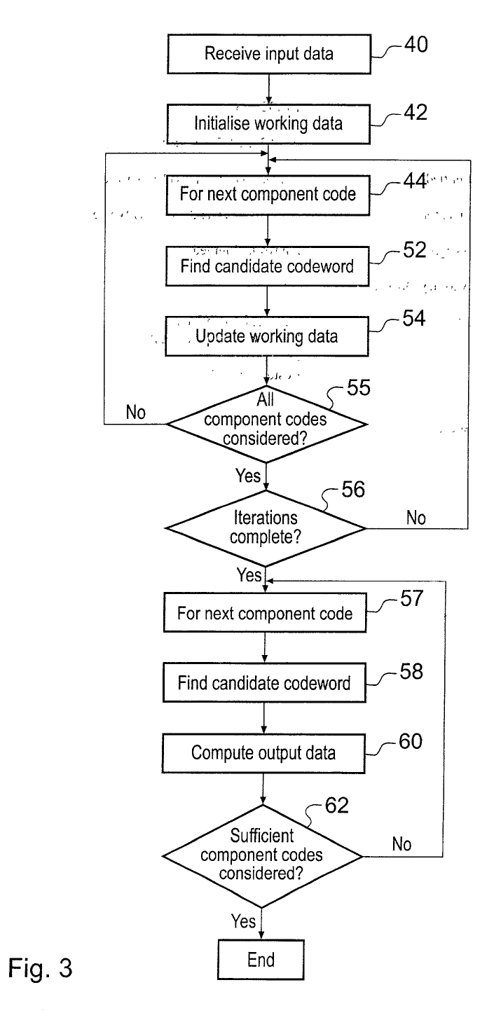

FIG. 3 is a flowchart showing the method in accordance with an aspect of the invention.

FIG. 2 shows a system in accordance with an aspect of the invention. Specifically, the source data is encoded using a product code in a forward error correction encoder 20, which computes parity bits. Thus, as is conventional, the encoded data is made up of a set of row codewords and an intersecting set of column codewords.

The source data and parity bits are transmitted by a transmitter 22 over a communications path 24. The present invention is particularly applicable to situations where the communications path 24 is an optical fibre, which transmits optical signals at high data rates. However, the invention is applicable to use with any form of communications path.

The transmitted signal, with any distortions and attenuation caused by the communications path, and with the addition of noise, is received in a receiver 26, which includes a 4-level quantizer. That is, for each received bit, the receiver outputs a polarity bit “1” or “0”, depending on whether the receiver determines that the transmitted bit is more likely to have been a “1” or a “0”, plus a confidence bit, the value of which indicates a degree of confidence in the detected polarity.

It should be noted that the present invention is also applicable to use with a receiver which includes a quantizer with more quantization levels. However, an advantage of the present invention is that it does not rely on a large number of quantization levels. Thus, if the quantization output is always considered to include one polarity bit, the number of confidence bits is preferably one, two or three. Three confidence bits corresponds to sixteen quantization levels.

The receiver output is supplied to a FEC decoder 28, which performs Forward Error Correction decoding. As is conventional, this process may be summarised in general terms as i) identifying whether a received binary sequence is a codeword; and ii) for cases where the received binary sequence is not a codeword, because of one or more errors in the received binary sequence as compared with the transmitted codeword, finding the codeword which is most likely to have been transmitted. As described above, for each received data bit, the receiver 26 outputs two bits, which are supplied as input data to the FEC decoder 28. Thus, for each data bit in the transmitted signal, the decoder 28 receives a two bit input data value, the meaning of which may be represented as follows:

TABLE 1

| Input data | Transmitted polarity | |
|---|---|---|
| value | more likely to have been: | Confidence level |
| 1, 1 | 1 | Higher |
| 1, 0 | 1 | Lower |
| 0, 0 | 0 | Lower |
| 0, 1 | 0 | Higher |

Thus, the first bit of the input data value is a polarity bit, and the second bit of the input data value is a confidence bit.

FIG. 3 is a flow chart illustrating a method in accordance with the invention. In step 40 of the process, the decoder 28 receives a block of data, which is made up of a plurality of row component codes and an intersecting plurality of column component codes.

As discussed above, in this preferred embodiment of the invention, the input data received by the decoder 28 comprises one polarity bit and one confidence bit in respect of each bit in the transmitted data. The operations carried out in the method are performed on the “working data”, which similarly comprise one polarity bit and one confidence bit in respect of each bit in the transmitted data. In step 42 of the method, the working data are initialised, and the initial values of the working data are the input data.

The method then moves to step 44, in which the decoder considers one component code. For example, the process first considers the row component codes in order, and then the column component codes in order, although other sequences are possible.

The process then moves to step 52, in which, based on the working data for each bit in the component code, the process attempts to find a single candidate codeword, which is close to the bit pattern formed by the polarity bits of the working data of that component code. Simple rules are defined to try to find such a candidate codeword.

For an Extended Hamming component code, one of the following is always true:

That the component code bit pattern is a valid codeword;

That a valid codeword may be obtained by inverting a unique single bit; or

That there are multiple valid codewords that may be obtained by inverting different pairs of bits.

In this exemplary embodiment of the invention, a candidate codeword is found by applying the following method:

If the component code is a valid codeword, then this is the candidate codeword;

If a single bit may be inverted to obtain a valid codeword, then codeword so obtained is the candidate codeword;

If a pair of bits may be inverted to obtain a valid codeword, and if, considering only those bits with low confidence values, a unique suitable pair exists, then this is the candidate codeword;

Otherwise, no candidate codeword is found.

Thus, a single candidate codeword is selected if that candidate codeword is clearly more probably correct than any other codeword, based on the value and confidence information for the bits comprising the candidate code, but, if two or more codewords are comparably probably correct, no candidate codeword is selected.

Based on the results of the search for a candidate codeword, the working data are modified in step 54 to form new working data.

The similarity between the component code and the chosen candidate codeword broadly indicates the reliability of the choice. This reliability can be placed into one of a small number of broad categories, and operations are then performed on the working data in accordance with the reliability categorization. In this case, there are five reliability categories, and a number of reliability categories of this order is found to be generally acceptable. For example, the number of reliability categories may be selected to be between three and ten. Then, put in general terms, if the choice of candidate codeword is assumed to be more reliable, then the operations tend to adjust the component code more strongly towards the selected candidate code. If the choice of candidate codeword is assumed to be less reliable, then the operations tend to adjust the component code less strongly towards the selected candidate code. These operations produce updated working data. For example, the following rules may be defined for updating the working data according to the results of the candidate codeword search.

If component code is a valid codeword: Candidate codeword has been chosen to be the component code. Action: CONFIRM all bits in component code;

If component code differs from a codeword in one bit and if this bit has a low confidence value: Candidate codeword has been chosen to be the component code with this bit inverted. Action: DOUBT this bit and CONFIRM all other bits;

If component code differs from a codeword in one bit and if this bit has a high confidence value: Candidate codeword has been chosen to be the component code with this bit inverted. Action: DOUBT this bit and NULL all other bits;

If component code differs from a codeword in two bits, and there is a unique pair of bits with low confidence values that, when inverted, yield a codeword: Candidate codeword has been chosen to be component code with these two bits inverted. Action: DOUBT these two bits and NULL all other bits;

Otherwise: No candidate codeword has been found: Action: NULL all bits.

As an alternative, in place of one, or more, of the NULL operations above we may perform a SKIP operation. However, other sets of operations could be defined in accordance with the general rules set out above. Further, in particular in the case of coding schemes with different minimum distances, different reliability categories could be defined.

The definitions of the terms NULL, CONFIRM, DOUBT and SKIP, as used above, are set out below. The term “one step” in these definitions means a change represented by a move from one row to an adjacent row in Table 1 above. A step in the direction of “1” means a step up in the table. A step in the direction of “0” means a step down in the table. A step in the direction of “1” from the top row gives the top row. A step in the direction of “0” from the bottom row gives the bottom row.

NULL: Next working data value takes input data value;

CONFIRM: Next working data value is input data value, moved one step in direction of the polarity bit of the current working value.

DOUBT: Next working data value is input data value, moved one step in the opposite direction to the polarity bit of the current working value.

SKIP: Next working data value is current working value.

When the working data have been updated according to these rules, it is determined in step 55 whether all of the component codes have been considered. If so, the process passes to step 56. Otherwise, the process returns to step 44, and the next component code is considered. As mentioned previously, the procedure may first consider all of the row component codes, and then all of the column component codes. Clearly, when considering the column component codes, each of the individual bits will already have been processed as part of their respective row component codes. Similarly, for all but the first iteration, when considering the row component codes, each of the individual bits will already have been processed as part of their respective column component codes.

If it is determined in step 55 that all of the component codes have been processed, one iteration is completed, and the procedure passes to step 56, in which it is determined whether the iterative updating procedure is completed. Thus, step 56 may determine whether a predetermined number of iterations have been completed. The predetermined number of iterations is chosen based on the received data rate and the available processing power in the decoder. A higher number of iterations will generally correct more errors, and four, five or six iterations have been found to provide an acceptable compromise between computational efficiency and error correcting capability.

If it is determined in step 56 that the iterative procedure is not completed, the procedure returns to step 44, and the first component code is processed again, using the same rules as before, but now considering the updated working data rather than the input data.

If it is determined in step 56 that the iterative procedure has finished, an output stage is entered, and the process passes to step 57, in which the component codes in one dimension are considered in turn. The procedure then passes to step 58. In step 58, a candidate codeword is found from the working data, using the same rules as described above with reference to step 52.

The process then passes to step 60, in which output data are computed. As with the input data and the working data, the output data comprises two data bits for each bit in the component code, namely a polarity bit and a confidence bit.

Depending on results of the search for a candidate codeword in step 58, an operation is performed on each bit of the component code to determine the output data. Simple rules are defined for computing the output data, according to the results of the candidate codeword search.

For example, the output data may be computed from the current working data according to the following rules, given the results of the search for a candidate codeword:

If component code is a valid codeword: CONFIRM all bits in component code;

If candidate codeword differs from component code in one bit and if this bit has “low confidence”: DOUBT this bit and CONFIRM all other bits;

If candidate codeword differs from component code in one bit and if this bit has “high confidence”: DOUBT this bit and NULL all other bits;

If candidate codeword differs from component code in two bits, and there is a unique pair of bits with “low confidence” that when inverted yield a codeword: DOUBT these two bits and NULL all other bits;

Otherwise no candidate codeword found: NULL all bits.

As an alternative, in place of one or more of the NULL operations above we may perform a SKIP operation.

In this output stage of the process, the four operations NULL, CONFIRM, DOUBT and SKIP are defined as follows. It should be noted that these definitions are not exactly the same as the definitions which apply during the iterative process at step 54. Again, however, one “step” in these definitions means a change represented by a move from one row to an adjacent row in Table 1. A step in the direction of “1” means a step up in the table. A step in the direction of “0” means a step down in the table. A step in the direction of “1” from the top row gives the top row. A step in the direction of “0” from the bottom row gives the bottom row.

NULL: Output data value takes current working data value.

CONFIRM: Output data value is present working data value, moved one step in the direction of the polarity bit of the current working data value.

DOUBT: Output data value is present working data value, moved one step in the opposite direction to the polarity bit of the current working data value.

SKIP: Output data value is current working data value.

The difference between these operations and the operations defined previously is that these operations retain or move one step from the current working data, whereas the operations used in step 54 retain or move one step from the input data. Thus, taking these two operations together, the result is that the output data can be up to two steps from the input data.

After the output data has been computed for one component code in step 60, the process passes to step 62, in which it is determined whether enough component codes have been considered. If so, the procedure ends. Otherwise, the procedure returns to step 57 for consideration of the next component code.

Thus, in this illustrated embodiment, the output processing considers each row component code once, or each column component code (but not both). In this way, each received bit is considered only once in the output processing, and one output value is computed for each received bit.

1. A method of decoding a received binary data signal, where the data has been encoded as a product of codes prior to transmission, the method comprising:
applying a multi-bit quantization to the received data signal to obtain input data comprising polarity information and confidence information for each bit in the received data signal;
for component codes in turn, in a first processing phase:
(a) attempting to select a candidate codeword based on the polarity and confidence information for the bits comprising the component code;
(b) according to the differences between the component code and the candidate codeword selected, modifying the polarity and confidence information for the component code; and
(c) repeating steps (a) and (b); and
in a second processing phase:
for sufficient component codes such that each bit in the received data is considered once:
(d) attempting to select a candidate codeword based on the polarity and confidence information for the bits of the modified input data; and
(e) according to the differences between the component code and the candidate codeword, modifying the polarity and confidence information for the component code to create the decoder output.

2. A method as claimed in claim 1, wherein, in step (b), the degree of modification of the polarity and confidence information for the component code depends on an assumed reliability of the selection of the candidate codeword.

3. A method as claimed in claim 2, wherein, if the component code is a codeword, that codeword is the selected candidate codeword, and the confidence information for bits of the component code may be increased.

4. A method as claimed in claim 2, wherein, if the choice of candidate codeword is assumed to be more reliable, then the modifications tend to adjust the component code more strongly towards the selected candidate code, and, if the choice of candidate codeword is assumed to be less reliable, then the operations tend to adjust the component code less strongly towards the selected candidate code.

5. A method as claimed in claim 4, wherein, if the choice of candidate codeword is assumed to be more reliable, more bits of the component code are modified than if the choice of candidate codeword is assumed to be less reliable.

6. A method as claimed in claim 1, wherein the confidence information comprises one, two or three bits.

7. A method as claimed in claim 1, wherein step (a) comprises:
selecting a single candidate codeword if that candidate codeword is clearly more probable than any other codeword, based on the value and confidence information for the bits comprising the candidate code, or,
otherwise, selecting no candidate codeword.

8. A method as claimed in claim 1, wherein, in step (e), the degree of modification of the polarity and confidence information for the component code depends on an assumed reliability of the selection of the candidate codeword.

9. A method as claimed in claim 8, wherein, if the component code is a codeword, that codeword is the selected candidate codeword, and the confidence information for bits of the component code may be increased.

10. A method as claimed in claim 8, wherein, if the choice of candidate codeword is assumed to be more reliable, then the modifications tend to adjust the component code more strongly towards the selected candidate code, and, if the choice of candidate codeword is assumed to be less reliable, then the operations tend to adjust the component code less strongly towards the selected candidate code.

11. A method as claimed in claim 1, wherein step (d) comprises:
selecting a single candidate codeword if that candidate codeword is clearly more probable than any other codeword, based on the value and confidence information for the bits comprising the candidate code, or,
otherwise, selecting no candidate codeword.

12. A method as claimed in claim 1, wherein, in step (b) any modifications are made to the input data to form new working data.

13. A method as claimed in claim 1 or 12, wherein, in step (e) any modifications are made to the working data to form output data.

14. A method as claimed in claim 1, wherein the data has been encoded as a product of dₘᵢₙ=4 codes prior to transmission.

15. A method as claimed in claim 1, wherein the data has been encoded as an Extended Hamming code before transmission.

16. A method as claimed in claim 1, comprising applying a multi-bit quantization to the received data such that the polarity information and confidence information for each bit in the received data signal are represented by up to four bits.

17. A method as claimed in claim 16, comprising applying a two-bit quantization to the received data signal, where the two bits represent the polarity information and confidence information for each bit in the received data signal.

18. A method as claimed in claim 1, wherein, in step (c), steps (a) and (b) are repeated a predetermined number of times.

19. A method as claimed in claim 1, wherein, in step (b), the modifications comprise one or more of the operations CONFIRM, DOUBT, NULL AND SKIP, as defined herein.

20. A method as claimed in claim 1, wherein, in step (e), the modifications comprise one or more of the operations CONFIRM, DOUBT, NULL AND SKIP, as defined herein.

21. A method of decoding a received binary data signal, where the data has been encoded as a product of codes prior to transmission, the method comprising:
applying a multi-bit quantization to the received data signal to obtain input data comprising polarity information and confidence information for each bit in the received data signal;
defining a small number of reliability categories based on degrees of similarity between component codes and candidate codewords;
for component codes in turn, in a first processing phase:
(a) attempting to select a candidate codeword based on the polarity and confidence information for the bits comprising the component code and assigning any selected candidate codeword to one of said reliability categories;
(b) modifying the polarity and confidence information for the component code based on the assigned reliability category; and
(c) repeating steps (a) and (b); and
in a second processing phase:
for sufficient component codes such that each bit in the received data is considered once:
(d) attempting to select a candidate codeword based on the polarity and confidence information for the bits comprising the modified component code and assigning any selected candidate codeword to one of said reliability categories; and
(e) modifying the polarity and confidence information for the modified component code based on the assigned reliability category to create the decoder output.

22. A method as claimed in claim 21, wherein step (a) comprises:
selecting a single candidate codeword if that candidate codeword is clearly more probable than any other codeword, based on the value and confidence information for the bits comprising the candidate code, or,
otherwise, selecting no candidate codeword.

23. A method as claimed in claim 21, wherein step (d) comprises:
selecting a single candidate codeword if that candidate codeword is clearly more probable than any other codeword, based on the value and confidence information for the bits comprising the candidate code, or,
otherwise, selecting no candidate codeword.

24. A method as claimed in claim 21, wherein, in step (b), if the choice of candidate codeword is assumed to be more reliable, then the modifications tend to adjust the component code more strongly towards the selected candidate code, and, if the choice of candidate codeword is assumed to be less reliable, then the operations tend to adjust the component code less strongly towards the selected candidate code.

25. A method as claimed in claim 24, wherein the modifications tend to adjust more bits of the component code if the choice of candidate codeword is assumed to be more reliable, and fewer bits if the choice of candidate codeword is assumed to be less reliable.

26. A method as claimed in claim 22, wherein, in step (e), if the choice of candidate-codeword is assumed to be more reliable, then the modifications tend to adjust the component code more strongly towards the selected candidate code, and, if the choice of candidate codeword is assumed to be less reliable, then the operations tend to adjust the component code less strongly towards the selected candidate code.

27. A method as claimed in claim 26, wherein the modifications tend to adjust more bits of the component code if the choice of candidate codeword is assumed to be more reliable, and fewer bits if the choice of candidate codeword is assumed to be less reliable.

28. A method as claimed in claim 21, wherein, in step (b), the modifications comprise one or more of the operations CONFIRM, DOUBT, NULL AND SKIP, as defined herein.

29. A method as claimed in claim 21, wherein, in step (e), the modifications comprise one or more of the operations CONFIRM, DOUBT, NULL AND SKIP, as defined herein.

30. A decoder, for use in a system in which data has been encoded as a product of codes prior to transmission, and in which a multi-bit quantization has been applied to the received data signal to obtain input data comprising polarity information and confidence information for each bit in the received data signal, wherein the decoder is adapted to:
for component codes in turn, in a first processing phase:
(a) attempt to select a candidate codeword based on the polarity and confidence information for the bits comprising the component code;
(b) according to the differences between the component code and the candidate codeword selected, modify the polarity and confidence information for the component code; and
(c) repeat steps (a) and (b); and
in a second processing phase:
for sufficient component codes such that each bit in the received data is considered once:
(d) attempt to select a candidate codeword based on the polarity and confidence information for the bits of the modified input data; and
(e) according to the differences between the component code and the candidate codeword, modify the polarity and confidence information for the component code to create the decoder output.

31. A receiver, for use in a system in which data has been encoded as a product of codes prior to transmission, the receiver comprising:
means for applying a multi-bit quantization to a received data signal to obtain input data comprising polarity information and confidence information for each bit in the received data signal, and
a decoder, wherein the decoder is adapted to:
for component codes in turn, in a first processing phase:
(a) attempt to select a candidate codeword based on the polarity and confidence information for the bits comprising the component code;
(b) according to the differences between the component code and the candidate codeword selected, modify the polarity and confidence information for the component code; and
(c) repeat steps (a) and (b); and
in a second processing phase:
for sufficient component codes such that each bit in the received data is considered once:
(d) attempt to select a candidate codeword based on the polarity and confidence information for the bits of the modified input data; and
(e) according to the differences between the component code and the candidate codeword, modify the polarity and confidence information for the component code to create the decoder output.

32. A decoder, for use in a system in which data has been encoded as a product of codes prior to transmission, and in which a multi-bit quantization has been applied to the received data signal to obtain input data comprising polarity information and confidence information for each bit in the received data signal, wherein the decoder is adapted to:
define a small number of reliability categories based on degrees of similarity between component codes and candidate codewords;
for component codes in turn, in a first processing phase:
(a) attempt to select a candidate codeword based on the polarity and confidence information for the bits comprising the component code and assign any selected candidate codeword to one of said reliability categories;
(b) modify the polarity and confidence information for the component code based on the assigned reliability category; and
(c) repeat steps (a) and (b); and
in a second processing phase:
for sufficient component codes such that each bit in the received data is considered once:
(d) attempt to select a candidate codeword based on the polarity and confidence information for the bits comprising the modified component code and assign any selected candidate codeword to one of said reliability categories; and
(e) modify the polarity and confidence information for the modified component code based on the assigned reliability category to create the decoder output.

33. A receiver, for use in a system in which data has been encoded as a product of codes prior to transmission, the receiver comprising:
means for applying a multi-bit quantization to a received data signal to obtain input data comprising polarity information and confidence information for each bit in the received data signal, and
a decoder, wherein the decoder is adapted to:
define a small number of reliability categories based on degrees of similarity between component codes and candidate codewords;
for component codes in turn, in a first processing phase:
(a) attempt to select a candidate codeword based on the polarity and confidence information for the bits comprising the component code and assign any selected candidate codeword to one of said reliability categories;
(b) modify the polarity and confidence information for the component code based on the assigned reliability category; and
(c) repeat steps (a) and (b); and
in a second processing phase:
for sufficient component codes such that each bit in the received data is considered once:
(d) attempt to select a candidate codeword based on the polarity and confidence information for the bits comprising the modified component code and assign any selected candidate codeword to one of said reliability categories; and
(e) modify the polarity and confidence information for the modified component code based on the assigned reliability category to create the decoder output.
